(19) United States
(12) Patent Application Publication
(10) Pub. No.: US 2024/0304690 A1
(43) Pub. Date: Sep. 12, 2024

(54) FIELD EFFECT TRANSISTOR

(71) Applicant: The Research Foundation for The State University of New York, Albany, NY (US)

(72) Inventors: Woongje SUNG, Niskayuna, NY (US); Sundar Isukapati, Albany, NY (US)

(21) Appl. No.: 18/600,700

(22) Filed: Mar. 9, 2024

Related U.S. Application Data
(60) Provisional application No. 63/451,253, filed on Mar. 10, 2023.

(51) Int. Cl. H01L 29/417; H01L 27/092; H01L 29/16

(52) U.S. Cl. CPC H01L 29/41783; H01L 27/092; H01L 29/1608

(57) ABSTRACT

Embodiments herein include a substrate; a semiconductor layer formed over the substrate; a source formed in the semiconductor layer; a drain formed in the semiconductor layer, whereon the drain is disposed laterally relative to the source; and a gate.

### CROSS REFERENCE TO RELATED APPLICATIONS

This application claims the benefit of priority to U.S. Provisional Patent Application No. 63/451,253, filed Mar. 10, 2023, entitled, “Lateral SIC HV MOSFET Design and Isolation Technique”, which is incorporated by reference herein in its entirety.

### GOVERNMENT RIGHTS STATEMENT

This invention was made with government support under DE-AR0001028 awarded by the U.S. Department of Energy. The U.S. government has certain rights in the invention.

### BACKGROUND

Embodiments herein relate generally to field effect transistors and specifically to metal oxide semiconductor field effect transistors (MOSFETs).

MOSFETs are selected for different applications based on a variety of parameters including maximum rating parameters and electrical performance parameters. Maximum rating parameters include, e.g., maximum drain to source voltage, maximum gate to source voltage, continuous drain current, pulsed drain current and total power dissipation. Electrical performance parameters include, e.g., drain to source breakdown voltage, gate threshold voltage, gate to source leakage current, drain to source leakage current, drain to source on state resistance, and forward transconductance.

Semiconductor materials for use in fabrication of MOSFETs include, e.g., silicon (Si), silicon carbide (SiC), gallium nitride (GaN), aluminum nitride (AlN), and germanium (Ge).

### BRIEF DESCRIPTION

There is set forth herein, according to one embodiment, a field effect transistor comprising a substrate; a semiconductor layer formed over the substrate; a source formed in the semiconductor layer; a drain formed in the semiconductor layer, whereon the drain is disposed laterally relative to the source; and a gate; wherein a spacing distance of the gate to the drain is greater than a spacing distance of the source to the drain.

There is set forth herein, according to one embodiment, a field effect transistor comprising a substrate; a semiconductor layer formed over the substrate; a source formed in the semiconductor layer; a drain formed in the semiconductor layer, whereon the drain is disposed laterally relative to the source; a gate having a gate dielectric; and wherein the field effect transistor is operative in a blocking mode in which the field effect transistor supports a blocking mode drain voltage, and wherein the field effect transistor includes shielding so that the gate is shielded from the blocking mode drain voltage.

There is set forth herein, according to one embodiment, a field effect transistor comprising a substrate; a silicon carbide semiconductor layer formed over the substrate; a source formed in the silicon carbide semiconductor layer; a drain formed in the silicon carbide semiconductor layer, whereon the drain is disposed laterally relative to the source; a P well formed about the source, wherein the P well is spaced apart from the drain; and a gate having gate dielectric; wherein a spacing distance between the gate dielectric of the gate and a drain contact of the drain is greater than a spacing distance between a source contact of the source and the drain contact of the drain.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A is a cross sectional view of a system defining a field effect transistor according to one embodiment;

FIG. 1B is top schematic layout view of a system defining a field effect transistor according to one embodiment;

FIG. 1C is a cross sectional unicell view of a system defining a field effect transistor according to one embodiment;

FIG. 1D is a cross sectional view of a system defining a field effect transistor according to one embodiment;

FIG. 1E is a cross sectional view of a system defining an integrated circuit incorporating field effect transistors according to one embodiment;

FIG. 1F is a cross sectional view of a system defining an integrated circuit incorporating field effect transistors according to one embodiment;

FIG. 2A depicts a SEM cross-section of the gate unshielded device and inset shows the schematic cross-section. As seen in the schematic, the area at the edge of the gate electrode is where there will be an increase in the electric field leading to an increase in the gate leakage;

FIG. 2B depicts a SEM cross-section of the gate shielded device and the inset shows the schematic cross-section. As seen in the schematic, the gate electrode is completely shielded from the p-top region and hence is unaltered by the design of the p-top leading to effective distribution of electric field in the gate oxide;

FIG. 3 depicts a simulated electric fields of the gate unshielded HV lateral nMOSFET and the (b) simulated electric field cross-section of the gate shielded HV lateral nMOSFET;

FIG. 4 depicts a simulated electric field profiles of the gate unshielded and gate shielded devices of lateral HV nMOSFETs at the breakdown; the gate unshielded device shows a large electric field raise at the edge of the gate electrode while the electric field in the gate shielded device is greatly reduced;

FIG. 5 depicts a measured gate-source current for the gate unshielded and gate shielded devices; the gate unshielded device shows the increase in the gate current with the increase in the drain-source voltage while the gate shielded device remains unaltered;

FIG. 6 depicts measured drain-source current for the gate unshielded and gate shielded devices; the gate unshielded device shows the increase in the drain-source current due to the increase in the gate-source current with the increase in drain-source voltage; and

FIG. 7 depicts the typical forward blocking behavior of the lateral nMOSFET with gate shielded device design and variation in the Lgap of the nMOSFET; the blocking capability of 700 V is demonstrated at the drain current of 100 μA and Vgs=0 V.

### DETAILED DESCRIPTION

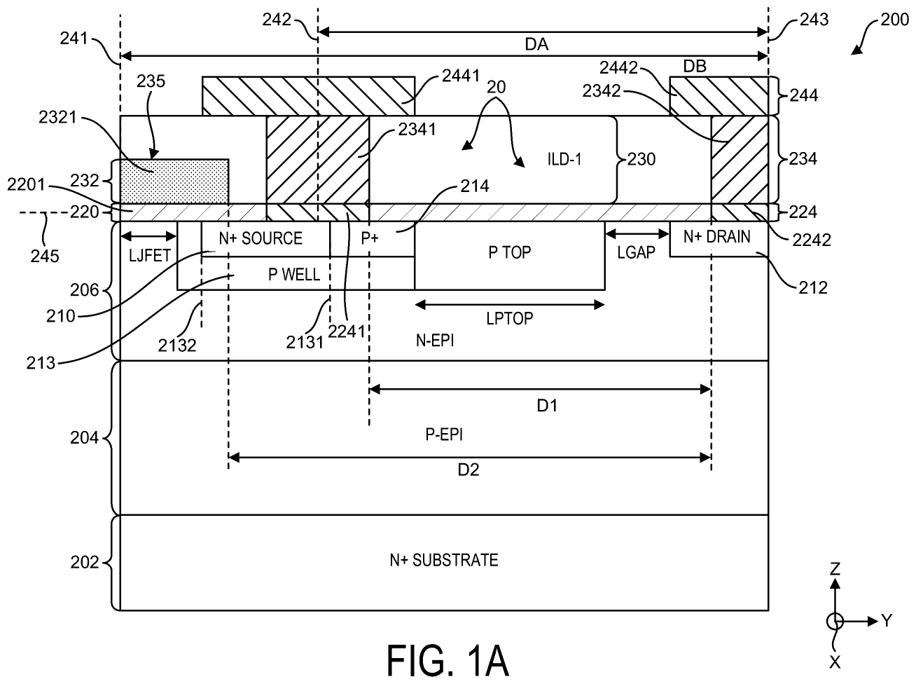

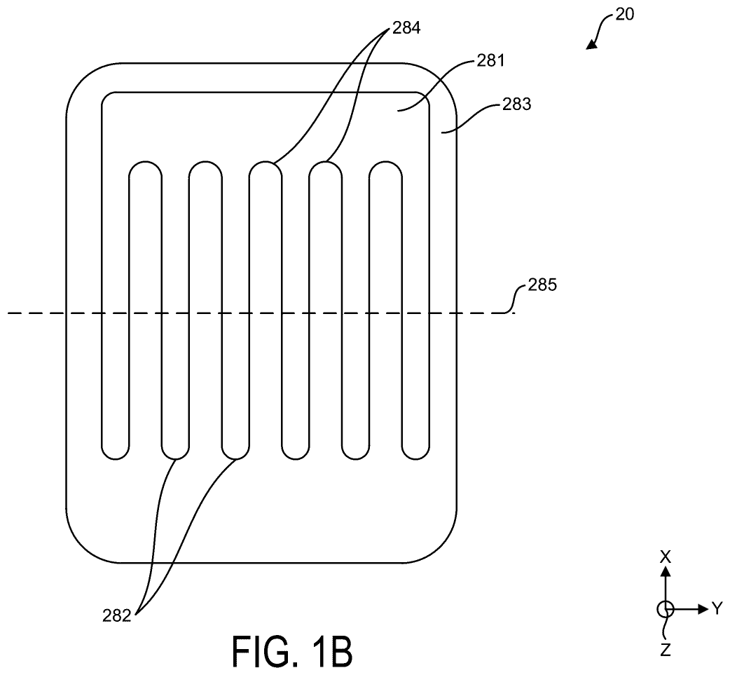

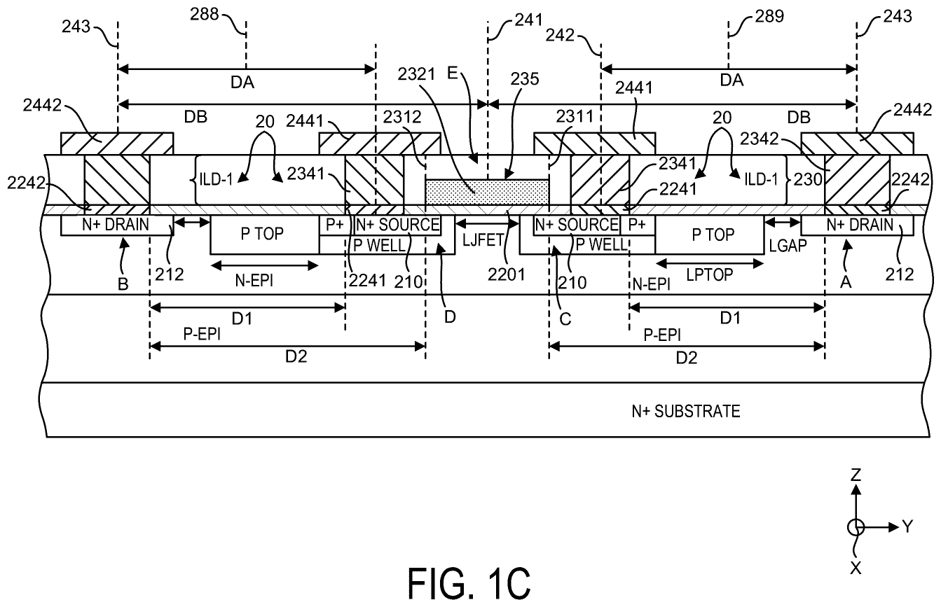

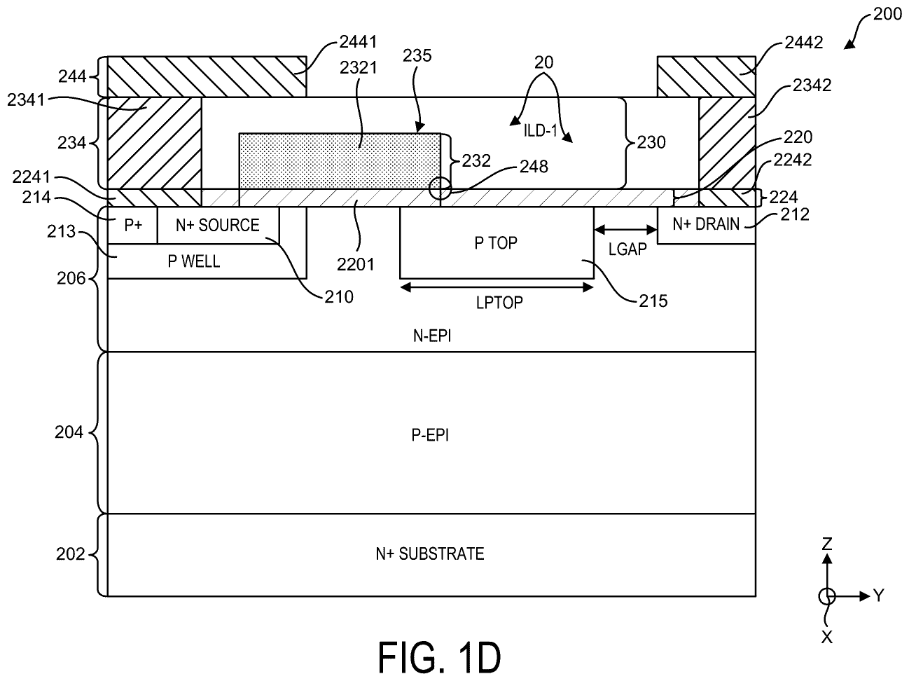

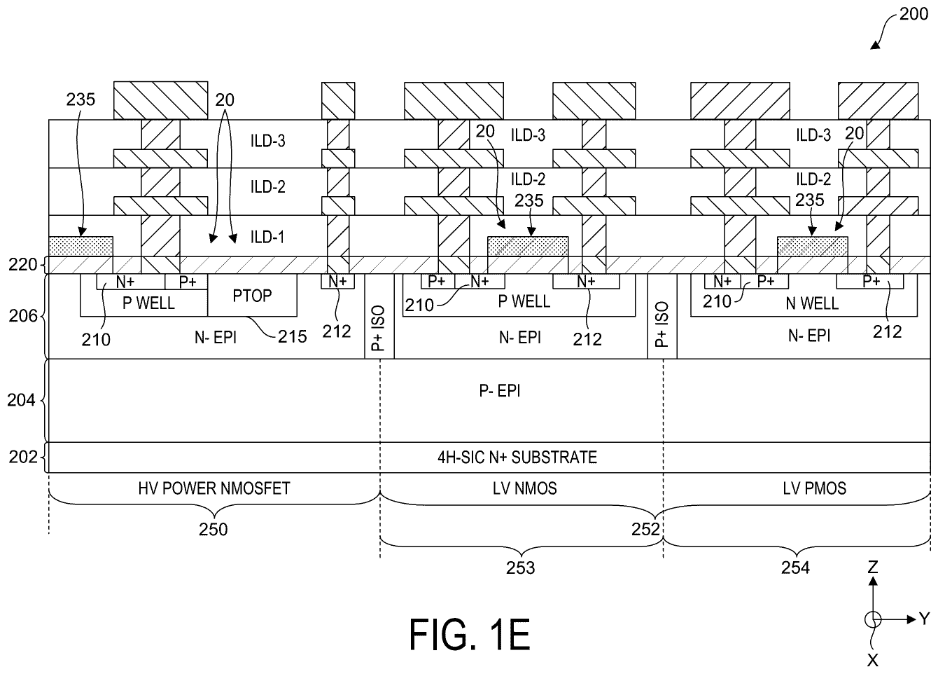

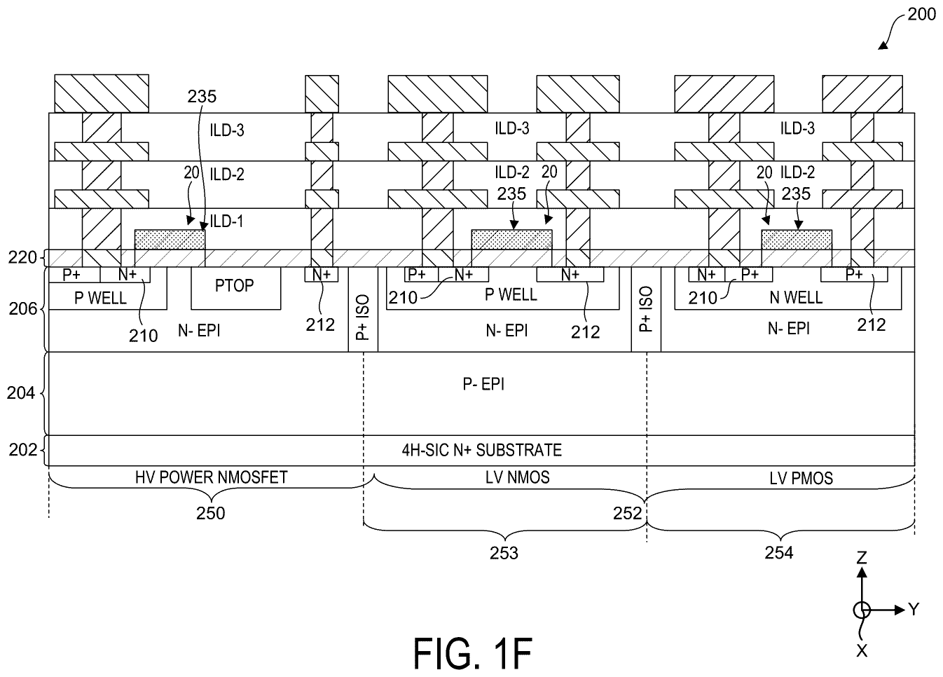

System 200 as shown in FIG. 1A can include a specific architecture for realization of various performance advantages in a field effect transistor. System 200 can include substrate 202, semiconductor layer 204, and semiconductor layer 206. In one embodiment, semiconductor layer 204 can be provided as a P doped layer, and in one embodiment can be lightly doped (P− doped). In one embodiment, semiconductor layer 206 can be provided as an N doped layer, and in one embodiment can be lightly doped (N− doped). Substrate 202 can be provided by 4H—SiC N+ substrate. Semiconductor layer 204 can be epitaxially grown on substrate 202, and semiconductor layer 206 can be epitaxially grown on semiconductor layer 204. Semiconductor layer 204 and semiconductor layer 206 can be pre-formed on the described commercially available wafer or can be custom grown. System 200 throughout the views defines a circuit structure.

System 200 can include a MOSFET 20 defined by source 210, drain 212, and gate 235. MOSFET 20 can include a lateral MOSFET architecture. In accordance with a lateral MOSFET architecture, drain 212 can be disposed laterally with respect to source 210, e.g., so that a horizontally extending plane running parallel to the depicted Y axis of the reference coordinate system can intersect the source 210 and drain 212. In further aspects, gate 235 can include gate electrode 2321 and gate dielectric 2201, wherein gate dielectric 2201 herein can refer to a section of dielectric layer 220 aligned under gate electrode 2321. In one embodiment, gate electrode can include, e.g., polysilicon or metal, and oxide forming gate oxide can be provided by silicon dioxide (SiO2). While the field effect transistor is referred to as a metal oxide semiconductor field effect transistor (MOSFET), embodiments herein recognize that gate electrode 2321 defining gate 235 can be formed of a conductive non-metal, e.g., polysilicon.

System 200 can define a MOSFET 20 provided by a lateral MOSFET that includes source 210 and drain 212 disposed laterally relative to one another. Source 210 and drain 212 can be formed by appropriate doping of semiconductor layer 206, e.g., by ion implantation or diffusion. System 200 can also include a P well region 213 that surrounds source 210 formed bottom adjacent and side adjacent to source 210. System 200 can also include a P+ region formed side adjacent to source 210 and bottom adjacent to source contact 2241.

System 200 can include dielectric layer 220, contact layer 224, dielectric layer 230, vias layer 234, and metallization layer 244. Dielectric layer 220 can be deposited on semiconductor layer 206 after doping of semiconductor layer 206. Subsequent to depositing dielectric layer 220, electrode material layer 232 can be deposited on dielectric layer 220 and can subsequently be patterned to define gate electrode 2321 defining gate 235. Dielectric layer 230 can subsequently be deposited over electrode material layer 232 and dielectric layer 220. Once planarized, dielectric layer 230 can be subject to etching to define trenches which can be filled by conductive material layer defining vias layer 234 to define vias 2341 and 2342.

After formation of dielectric layer 220, dielectric layer 220 can be etched to form trenches. Contact layer 224 can be deposited in the formed trenches and then planarized to define source contact 2241 that contacts source 210 and drain contact 2242 that contacts drain 212. Source 210 can include associated source conductive material formations including source contact 2241, source vias 2341, and source wiring 2441. Drain 212 can include associated source conductive material formations including drain contact 2242, drain vias 2342, and drain wiring 2442. The conductive material formations including source contact 2241, source vias 2341, source wiring 2441, drain contact 2242, drain vias 2342, and drain wiring 2442 can be formed of conductive material, e.g. metal, e.g., aluminum, copper, gold, silver, nickel and the like.

In one embodiment, MOSFET 20 can be configured as a high voltage (HV) power MOSFET that features a breakdown voltage of about 100V or greater. In one embodiment, for increasing breakdown voltage of MOSFET 20, semiconductor layer 204 and semiconductor layer 206 can be formed of silicon carbide (SiC). SiC features a wide bandgap 3-3.2 eV, high breakdown field 2.5-3 MV/cm and large thermal conductivity 4-5 W/cm-K. Embodiments herein recognize that in vertical MOSFETs (wherein a source and drain are in vertical orientation), MOSFET breakdown voltage can be increased by increasing a source to drain spacing distance. Embodiments herein recognize that increasing drain spacing in a lateral MOSFET design (while potentially helpful in increasing breakdown voltage) will increase device pitch and consume wafer real estate in the (top view) X-Y plane. Accordingly, embodiments herein include features for improving X-Y plane space economization while increasing breakdown voltage of MOSFET 20 as well as additional performance characteristics.

Embodiments herein recognize that when SiC, featuring a high breakdown field, is selected as the material for semiconductor layer 206, other materials of MOSFET 20 can experience breakdown prior to the components formed of SiC, including dielectric material of gate dielectric 2201. Embodiments herein can include features for realization of reduced electric field at gate dielectric 2201.

Operation of system 200 as shown in FIG. 1A is now described. When gate voltage is applied to gate electrode 2321 to switch MOSFET ON, charges can be attracted underneath the gate dielectric 2201 to invert the polarity of P well 213 adjacent P well 213 and gate dielectric 2201 to define a channel in P well 213 adjacent gate dielectric 2201 between source 210 and the body of semiconductor layer 206. When the channel is active and “ON”, there can be established a conductive path between source 210 and drain 212 through the channel and the body of semiconductor layer 206.

In a blocking mode of operation, the defined channel in P well 213 adjacent gate dielectric 2201 between source 210 and the body of semiconductor layer 206 can be “OFF”, source 210 and gate 235 can be grounded and blocking mode drain voltage (i.e., up to the breakdown voltage) can be applied to drain 212. Embodiments herein recognize that a blocking mode drain voltage can be supported by structures within MOSFET 20 that define the minimum distance between the high voltage applied at drain 212. Accordingly, embodiments herein recognize that when both source 210 and gate 235 are grounded, and the distance from gate 235 to drain 212 is less than the distance from source 210 to drain 212 as shown in FIG. 1D, gate 235 including gate dielectric 2201 can support a blocking mode drain voltage in a blocking mode, such that electric field of significant strength can be imposed at gate dielectric 2201.

In one aspect, MOSFET 20, for shielding gate 235 from a blocking mode drain voltage, can be configured so that gate 235 is disposed a greater distance from drain 212 than source 210. According to such configuration, a spacing distance of gate 235 to drain 212 can be greater than a spacing distance of the source 210 to drain 212. In one aspect, MOSFET 20, for shielding gate 235 from blocking mode drain voltage, can be configured so that a gate dielectric 2201 of gate 235 (defined by a portion of dielectric layer 220 aligned under gate electrode 2321) is disposed a greater distance from drain 212 than source 210. According to such configuration, a spacing distance of gate dielectric 2201 to a drain contact 2242 of the drain 212 can be greater than a spacing distance of a source contact 2241 of the source 210 to the drain contact 2242 of the drain 212. In one aspect, providing MOSFET 20 so that a gate dielectric 2201 of gate 235 (defined by a portion of dielectric layer 220 aligned under gate electrode 2321) is disposed a greater distance from drain 212 than source 210, can be characterized by source contact 2241 of source 210 being disposed closer to drain contact 2242 of drain 212 than gate dielectric 2201. In another aspect, in reference to the gate shielded architecture of FIGS. 1A and 1C, a spacing distance between a corner of a gate electrode 2321 of the gate 235 adjacent gate dielectric 2201 (the location of the gate 235 in FIG. 1A mapping to gate corner 248 depicted in FIG. 1D) and a drain contact 2242 of the drain 212 is greater than a spacing distance between a source contact 2241 of the source and the drain contact 2242 of drain 212.

In one embodiment, the relative spacing distances between drain contact 2242 and source contact 2241 and between drain contact 2242 and gate dielectric 2201 can be based on the closest point spacing distances, i.e., D1<D2 as shown in FIG. 1A. In one embodiment, the relative distances between drain contact 2242 and source contact 2241 and between drain contact 2242 and gate dielectric 2201 can be based on geometric center distances, i.e., DA<DB as shown in FIG. 1A (as measured in the horizontal X-Y plane), wherein axes 241, 242, and 243 are vertically extending center axes of gate dielectric 2201, source contact 2241 and drain contact 2242 respectively. In one embodiment, FIGS. 1A and 1C can be regarded to be “to scale” in terms of the depicted relative distances between source 210 and its associated conductive material formations, drain 212 and its associated conductive material formations, and gate 235 including gate electrode 2321 and gate dielectric 2201 aligned under gate electrode 2321.

Accordingly, there is set forth herein, in one embodiment, a substrate 202; a semiconductor layer 206 formed over the substrate 202; a source 210 formed in the semiconductor layer 206; a drain 212 formed in the semiconductor layer 206, whereon the drain 212 is disposed laterally relative to the source 210; a gate 235 having a gate dielectric 2201; wherein the field effect transistor provided by MOSFET 20 is characterized by a spacing distance of the gate 235 to the drain 212 being greater than a spacing distance of the source 210 to the drain 212.

Accordingly, there is set forth herein, in one embodiment, a field effect transistor provided by MOSFET 20 comprising substrate 202; a silicon carbide semiconductor layer formed over the substrate, e.g., semiconductor layer 206 when formed of silicon carbide; a source 210 formed in the semiconductor layer 206; a drain 212 formed in the semiconductor layer 206, whereon the drain 212 is disposed laterally relative to the source 210; a P well 213 formed about source 210, wherein the P well 213 is spaced apart from drain 212; a gate 235 having a gate dielectric 2201; wherein the field effect transistor provided by MOSFET 20 is characterized by a spacing distance between a gate dielectric 2201 of the gate 235 and a drain contact 2242 of the drain 212 being greater than a spacing distance between a source contact 2241 of source 210 and the drain contact 2242 of drain 212.

In one embodiment, MOSFET 20 can include a finger architecture as shown in the schematic layout top view of FIG. 1B showing a general arrangement of source sections of source 210 and drain sections of drain 212 in MOSFET (gate 235 not shown in the schematic layout top view of FIG. 1B). Referring to FIG. 1B, MOSFET 20 can include, from a top X-Y plane view, an internal structure 281 having fingers 282 extending in parallel with the X axis of the reference coordinate system and external structure 283 having fingers 284 extending in parallel with the X axis of the reference coordinate system. In one embodiment, source 210 can be defined on internal structure 281 and drain 212 can be defined on external structure 283. In one embodiment, drain 212 can be defined on internal structure 281 and source 210 can be defined on external structure 283. In one embodiment, the cross-sectional view of system 200 in FIG. 1A generally corresponds to a cut along plane 285 in the schematic layout top view of FIG. 1B extending in parallel with the Z-Y plane of the depicted reference coordinate system. With the architecture of FIG. 1B, source 210 can be defined by a plurality of source sections, drain 212 can be defined by a plurality of drain sections, and gate 235 can be defined by a plurality of gate sections.

The referenced sectional aspect, wherein source 210 can be defined by a plurality of source sections, drain 212 can be defined by a plurality of drain sections, and gate 235 can be defined by a plurality of gate sections is described further in reference to FIG. 1C in which there are shown, in accordance with the configuration of FIGS. 1A and 1B, drain 212 defined by a plurality of spaced apart (from the perspective of the cross sectional view of FIG. 1C) source sections of source 210 at “A” and “B”, drain sections of drain 212 at “C” and “D” and gate sections of gate 235 at “E” (addition sections inferred by expansion of the cross-section). In one embodiment, MOSFET 20 can be absent of the architecture depicted schematically in FIG. 1B and can include a source, drain and gate defined by respective single sections.

In reference to FIG. 1C, vertically extending planes 288 and 289 can define boundaries between the fingers 282 and 284 of FIG. 1B. Referring to FIG. 1C, gate 235 (including gate electrode 2321 and gate dielectric 2201) can include a gate section having a first side edge delimited by vertically extending plane 2311 and a second, opposite side edge delimited by vertically extending plane 2312 wherein each of the first side edge and the second side edge are aligned over source 210 by being aligned over respective different source sections. By being aligned as described, vertically extending plane 2311 and vertically extending plane 2312 can pass through the respective different source sections as can be seen by FIG. 1C. In an embodiment according to FIGS. 1A-1C, “source” fingers (FIG. 1B) can include first and second source sections, and a common gate section.

Accordingly, there is set forth herein, in one embodiment, a field effect transistor provided by MOSFET 20 comprising a substrate 202; a semiconductor layer 206 formed over the substrate; a source 210 formed in the semiconductor layer; a drain 212 formed in the semiconductor layer 206, wherein drain 212 is disposed laterally relative to source 210; and a gate 235; wherein a spacing distance of the gate 235 to the drain 212 is greater than a spacing distance of the source 210 to the drain 212, wherein gate 235 includes a first side edge, e.g., bounded by vertically extending plane 2311 and an opposite second side edge, e.g., bounded by vertically extending plane 2312, wherein the first side edge of the gate is aligned over the source 210, and wherein the opposite second side edge of the gate 235 is aligned over the source 210.

In reference to FIG. 1A, source 210 can include drain side edge delimited by vertically extending plane 2131 and a second, opposite side edge delimited by vertically extending plane 2132, wherein the drain side edge of source 210 is disposed closer to drain 212 than the opposite side edge of source 210. As seen in FIG. 1A, the described opposite side edge of source 210 is aligned under gate 235 (including gate electrode 2321 and gate dielectric 2201). By being aligned as described vertically extending plane 2132 delimiting the second opposite side edge of source 210 can through gate 235. The described configuration of source 210 and gate 235 can facilitate shielding of gate 235 from blocking mode drain voltage.

Accordingly, there is set forth herein, in one embodiment, a field effect transistor provided by MOSFET 20 comprising a substrate 202; a semiconductor layer 206 formed over the substrate; a source 210 formed in the semiconductor layer; a drain 212 formed in the semiconductor layer 206, wherein drain 212 is disposed laterally relative to source 210; and a gate 235; wherein a spacing distance of the gate 235 to the drain 212 is greater than a spacing distance of the source 210 to the drain 212, wherein source 210 includes a first drain side edge, e.g., bounded by vertically extending plane 2131 and an opposite second side edge, e.g., bounded by vertically extending plane 2132, wherein the first drain side edge of source 210 is closer to the drain 212 than the second opposite side edge of the source 210, and wherein the second opposite side edge of source 210 is aligned under gate 235.

In one embodiment, spacing distance relationships described herein apply on a half cell view basis, as set forth in FIG. 1A. In one embodiment, spacing distance relationships herein apply on unicell view basis, as set forth in FIG. 1C as well as on a half cell view basis, as set forth in FIG. 1A.

In the embodiment of FIG. 1A, each of the drain contact 2242, source contact 2241 and gate dielectric 2201 extend horizontally at a common elevation 245 as defined by the elevation of dielectric layer 220, which can be horizontally extending and contact layer 224, which can be horizontally extending.

Embodiments herein recognize that the architecture of FIG. 1A provides increased blocking mode drain voltage shielding to gate dielectric 2201 and reduced electric field strength at gate dielectric 2201. An alternate comparison structure configuration for system 200 of FIG. 1A is shown in FIG. 1D. In FIG. 1D illustrating system 200 defining a field effect transistor provided by MOSFET 20, gate dielectric 2201 of gate 235 is located closer to drain contact 2242 of drain 212 than source contact 2241 of source 210. Embodiments herein recognize that with the architecture of FIG. 1D characterized by gate corner 248 being located closer to drain 212 than source 210, gate corner 248 can support blocking mode drain voltage and significant electric field strength can be imposed at gate corner 248 defined at a bottom side edge of gate electrode 2321.

In one aspect, system 200 of FIG. 1A and system 200 of FIG. 1D can include a P doped P top region 215. P top region 215 can be configured by various parameters including doping, dimensions, and location so that an electric field of MOSFET 20 when operating in blocking mode is distributed according to a targeted electric field distribution profile. P top region 215, for example, can be configured to distribute an electric field for reduced electric field at gate corner 248 of gate electrode 2321, and additional corners defined within MOSFET, e.g., a corner of P well 213, and a corner of drain 212. Gate corner 248 can be defined at a bottom side edge of gate electrode 2321 adjacent to gate dielectric 2201. Embodiments herein recognize that electric field distribution performed by P top region 215 can be highly dependent on doping of P top region 215 which can be difficult to control. Embodiments herein recognize that where P top region 215 is underdoped, there can be significant electric field strength imposed at gate dielectric 2201 including at gate corner 248, even where P top region 215 is designed to reduce an electric field strength at gate dielectric 2201. By incorporating one or more feature configured to reduce a strength of electric field proximate a surface of semiconductor layer 206, MOSFET 20 can be configured as reduced surface field (RESURF) MOSFET.

Embodiments herein recognize that the gate shielded configuration of FIG. 1A, configured for reduced electric field strength at gate dielectric 2201, can reduce reliance on P top region 215 for electric field distribution, or eliminate reliance on P top region 215 altogether in certain applications.

Embodiments herein recognize that by reduction of an electric field strength at gate dielectric 2201, gate dielectric 2201 can be protected and breakdown of gate dielectric 2201 can be avoided. With breakdown of gate dielectric 2201 avoided, leakage current performance of MOSFET 20 can be improved. Configured according to the architecture of FIG. 1A, wherein breakdown of gate dielectric 2201 can be avoided, MOSFET 20 can feature reduced current leakage.

With breakdown of gate oxide 2210 avoided, the breakdown voltage of MOSFET 20 can be favorably limited by the breakdown of voltage of semiconductor material defining semiconductor layer 206, rather than a breakdown field of dielectric material, e.g., oxide forming gate dielectric 2201. Configured according to the architecture of FIG. 1A, MOSFET 20 can feature an increased breakdown voltage, e.g., a breakdown voltage dependent on breakdown field characteristics of material forming semiconductor layer 206 rather than a breakdown voltage dependent on a breakdown field of oxide forming gate dielectric 2201.

Table A presents design specifications for the MOSFET described in reference to FIG. 1A according to one embodiment.

TABLE A
(FIG. 1A design with gate shielding)

| Parameter | Value |
|---|---|
| N-epi | 2.5 μm ± 50% 6.5e16 cm⁻³ ± 50% |
| P-epi | 6 μm ± 50% 2e16 cm⁻³ ± 50% |
| Channel | 0.5 μm ± 50% |
| JFET (Ljfet) | 0.6 μm ± 50% |
| Ptop (Lptop) | 1.0 μm-10 μm |
| Gap (Lgap) | 1.5 μm ± 50% |
| P+ Source | 1.0 μm ± 50% |
| N+ Source | 2.1 μm ± 50% |

The MOSFET of FIG. 1A is shown integrated with external devices in reference to system 200 in FIG. 1E.

In FIG. 1E, there is shown system 200 defining an integrated circuit having high voltage (HV) MOSFET region 250 commonly fabricated on a common wafer with low voltage complementary metal oxide semiconductor (CMOS) region 252. Low voltage CMOS region 252 can include low voltage (LV) NMOS region 253 and low voltage PMOS region 254. HV MOSFET region 250 can be configured in accordance with system 200 as shown in FIG. 1A. Regions 250 and 252 can be repeated, e.g., tens to thousands, or millions of times, throughout a wafer scale structure on which system 200 is built.

According to an isolation architecture of system 200 as shown in FIG. 1E, system 200 of FIG. 1E can include doped isolation formation 260 for providing isolation between instances of high voltage MOSFET region 250 and instances of low voltage CMOS region 252, and doped isolation formation 262 for providing isolation between instances of low voltage NMOS region 253 and low voltage PMOS region 254.

In one embodiment, doped isolation formation 260 can be formed by ion implantation of semiconductor layer 206. In one embodiment, doped isolation formation 262 can be formed by ion implantation of semiconductor layer 206. The ion implantation of doped isolation formation 260 and doped isolation formation 262 can be performed using channel implantation. Embodiments herein recognize that the use of channel ion implantation facilitates increase in a depth dimension of doped isolation formation 260 and doped isolation formation 262 to significant depths, e.g., to about 2 μm or longer. In another aspect, the formation of doped isolation formation 260 and doped isolation formation 262 can be performed so that a depth of doped isolation formation 260 and doped isolation formation 262 extends to a top elevation of semiconductor layer 204, thus removing a leakage path between high voltage MOSFET region 250 and low voltage CMOS region 252, and between low voltage NMOS region 253 and low voltage PMOS region 254.

Embodiments herein recognize that voltages regarded to be HV and LV can be application dependent. In one embodiment, a HV MOSFET can refer to a MOSFET having a breakdown voltage of about 100V or greater. In one embodiment, a LV MOSFET can refer to a MOSFET having a breakdown voltage of about 50V or less. In FIG. 1F there is shown system 200 defining an integrated circuit according to the integrated circuit of FIG. 1E, with MOSFET 20 of high voltage MOSFET region 250 configured according to the architecture of FIG. 1D.

The integrated circuit also includes a substrate; a semiconductor layer formed over the substrate; a source formed in the semiconductor layer; a drain formed in the semiconductor layer, whereon the drain is disposed laterally relative to the source; a gate having gate oxide; and a source contact; where the source contact is disposed at first distance from a drain contact of the drain, where the gate oxide is disposed at a second distance from the drain contact, the second distance being longer than the first distance. Other embodiments of this aspect include corresponding computer systems, apparatus, and computer programs recorded on one or more computer storage devices, each configured to perform the actions of the methods.

Implementations may include one or more of the following features. The integrated circuit where the semiconductor layer is a silicon carbide layer. The semiconductor layer is a doped silicon carbide layer. The semiconductor layer is an epitaxially grown doped silicon carbide layer. The source contact is disposed intermediate the gate oxide and the drain. The semiconductor layer is formed on the semiconductor layer. The source, the drain and the gate define a high voltage power MOSFET region, and where the integrated circuit includes a low voltage CMOS region, the low voltage CMOS region including a low voltage NMOS region, and a low voltage PMOS region, where the low voltage CMOS region is defined by the substrate and the semiconductor layer.

One general aspect includes the field effect transistor also includes a substrate; a semiconductor layer formed over the substrate; a source formed in the semiconductor layer; a drain formed in the semiconductor layer, whereon the drain is disposed laterally relative to the source; a gate having a gate dielectric; where the field effect transistor is characterized by a spacing distance of the gate to the drain being greater than a spacing distance of the source to the drain.

Implementations may include one or more of the following features, the field effect transistor where the field effect transistor includes a P well formed about the source, the P well spaced apart from the drain. The spacing distance of the gate to the drain being greater than a spacing distance of the source to the drain is characterized by a spacing distance between a gate dielectric of the gate and a drain contact of the drain being greater than a spacing distance between a source contact of the source and the drain contact of the drain. A source contact of the source, a drain contact of the drain, and the gate dielectric extend at a common elevation, and where the spacing distance of the gate to the drain being greater than a spacing distance of the source to the drain is characterized by a spacing distance between a gate dielectric of the gate and a drain contact of the drain being greater than a spacing distance between a source contact of the source and the drain contact of the drain. The semiconductor layer is a doped silicon carbide layer. The gate includes a first edge and an opposite second edge, where the first edge is aligned over the source, and where the second edge is aligned over the source. The semiconductor layer is an epitaxially grown doped silicon carbide layer. The semiconductor layer is a silicon carbide layer. The semiconductor layer is a doped silicon carbide layer. The semiconductor layer is an epitaxially grown doped silicon carbide layer. The source is disposed intermediate the gate dielectric and the drain. The semiconductor layer is formed on the semiconductor layer. The source, the drain and the gate define a high voltage power MOSFET region, and where the integrated circuit includes a low voltage CMOS region, the low voltage CMOS region including a low voltage NMOS region, and a low voltage PMOS region, where the low voltage CMOS region is defined by the substrate and the semiconductor layer.

One general aspect includes, the field effect transistor also includes a substrate; a semiconductor layer formed over the substrate; a source formed in the semiconductor layer; a drain formed in the semiconductor layer, whereon the drain is disposed laterally relative to the source; a gate having a gate dielectric; and where the field effect transistor is operative in a blocking mode in which the field effect supports a voltage drop, and where the field effect transistor includes shielding so that the gate is shielded from the voltage drop.

Implementations may include one or more of the following features, the field effect transistor where the field effect transistor is configured so that in the blocking mode, the source and the gate are grounded. The shielding is characterized by a spacing distance of the gate to the drain being greater than a spacing distance of the source to the drain. The shielding is characterized by a spacing distance of the gate to the drain being greater than a spacing distance of the source to the drain, where the spacing distance of the gate to the drain being greater than a spacing distance of the source to the drain is characterized by spacing distance between a gate dielectric of the gate and a drain contact of the drain being greater than a spacing distance between a source contact of the source and the drain contact of the drain. The field effect transistor is configured so that in the blocking mode, the source and the gate are grounded, where the shielding is characterized by a spacing distance of the gate to the drain being greater than a spacing distance of the source to the drain, where the spacing distance of the gate to the drain being greater than a spacing distance of the source to the drain is characterized by spacing distance between a gate dielectric of the gate and a drain contact of the drain being greater than a spacing distance between a source contact of the source and the drain contact of the drain.

One general aspect includes, the field effect transistor also includes a substrate; a silicon carbide semiconductor layer formed over the substrate; a source formed in the semiconductor layer; a drain formed in the semiconductor layer, whereon the drain is disposed laterally relative to the source; a P well formed about the source, where the P well is spaced apart from the drain; a gate having gate dielectric; where the field effect transistor is characterized by a spacing distance between a gate dielectric of the gate and a drain contact of the drain being greater than a spacing distance between a source contact of the source and the drain contact of the drain.

The field effect transistor also includes a substrate; a semiconductor layer formed over the substrate; a source formed in the semiconductor layer; a drain formed in the semiconductor layer, whereon the drain is disposed laterally relative to the source. The transistor also includes a gate; where a spacing distance of the gate to the drain is greater than a spacing distance of the source to the drain.

The field effect transistor where the field effect transistor includes a P well formed about the source, the P well spaced apart from the drain. A spacing distance between a gate dielectric of the gate and a drain contact of the drain is greater than a spacing distance between a source contact of the source and the drain contact of the drain. A source contact of the source, a drain contact of the drain, and the gate dielectric extend at a common elevation, where a spacing distance between a gate dielectric of the gate aligned under a gate electrode of the gate and a drain contact of the drain is greater than a spacing distance between a source contact of the source and the drain contact of the drain. The semiconductor layer is a doped silicon carbide layer. The gate includes a first side edge and an opposite second side edge, where the first side edge of the gate is aligned over the source, and where the opposite second side edge of the gate is aligned over the source. The source includes a first drain side edge and an opposite second side edge, where the first drain side edge of the source is closer to the drain than the second opposite side edge of the source, and where the second opposite side edge of the source is aligned under the gate. The semiconductor layer is an epitaxially grown doped silicon carbide layer. The semiconductor layer is a silicon carbide layer. The semiconductor layer is a silicon carbide layer, where a source contact of the source, a drain contact of the drain, and the gate dielectric extend at a common elevation, where a spacing distance between a gate dielectric of the gate and a drain contact of the drain is greater than a spacing distance between a source contact of the source and the drain contact of the drain, where the field effect transistor includes a P well formed about the source, the P well being spaced apart from the drain. The semiconductor layer is an epitaxially grown doped silicon carbide layer. The source is disposed intermediate the gate and the drain. The source, the drain and the gate define a high voltage power MOSFET region, and where the integrated circuit includes a low voltage CMOS region, the low voltage CMOS region including a low voltage NMOS region, and a low voltage PMOS region, where the low voltage CMOS region is defined by the substrate and the semiconductor layer. The source, the drain and the gate define a high voltage power MOSFET region, and where the integrated circuit includes a low voltage CMOS region, the low voltage CMOS region including a low voltage NMOS region, and a low voltage PMOS region, where the low voltage CMOS region is defined by the substrate and the semiconductor layer, where the integrated circuit includes a doped formation isolating the high voltage power MOSFET region from the low voltage CMOS region, the doped formation extending an entire depth of the semiconductor layer, and being formed by use of channel ion implantation. The source, the drain and the gate define a high voltage power MOSFET region, and where the integrated circuit includes a low voltage CMOS region, the low voltage CMOS region including a low voltage NMOS region, and a low voltage PMOS region, where the low voltage CMOS region is defined by the substrate and the semiconductor layer, where the integrated circuit includes a doped formation isolating the high voltage power MOSFET region from the low voltage CMOS region, the doped formation extending an entire depth of the semiconductor layer, and being formed by use of channel ion implantation, where the integrated circuit includes a second doped formation isolating the low voltage NMOS region, and the low voltage PMOS region, the second doped formation extending an entire depth of the semiconductor layer, and being formed by use of channel ion implantation, where the semiconductor layer is a silicon carbide layer, where a source contact of the source, a drain contact of the drain, and the gate dielectric extend at a common elevation, where a spacing distance between a corner of a gate electrode of the gate adjacent the gate dielectric and a drain contact of the drain is greater than a spacing distance between a source contact of the source and the drain contact of the drain, where the field effect transistor includes a P well formed about the source, the P well being spaced apart from the drain, where the gate includes a first side edge and an opposite second side edge, where the first side edge of the gate is aligned over the source, and where the opposite second side edge of the gate is aligned over the source, where the source includes a first drain side edge and an opposite second side edge, where the first drain side edge of the source is closer to the drain than the second opposite side edge of the source, and where the second opposite side edge is aligned under the gate.

One general aspect includes the field effect transistor also includes a substrate; a semiconductor layer formed over the substrate; a source formed in the semiconductor layer; a drain formed in the semiconductor layer, whereon the drain is disposed laterally relative to the source. The transistor also includes a gate having a gate dielectric; and where the field effect transistor is operative in a blocking mode in which the field effect transistor supports a blocking mode drain voltage, and where the field effect transistor includes shielding so that the gate is shielded from the blocking mode drain voltage.

Implementations may include one or more of the following features. The field effect transistor where the shielding is characterized by a spacing distance of the gate to the drain being greater than a spacing distance of the source to the drain. The shielding is characterized by a spacing distance between a gate dielectric of the gate and a drain contact of the drain being greater than a spacing distance between a source contact of the source and the drain contact of the drain. The field effect transistor is configured so that in the blocking mode, the source and the gate are grounded, where the shielding is characterized by a spacing distance of the gate to the drain being greater than a spacing distance of the source to the drain, where the spacing distance of the gate to the drain being greater than a spacing distance of the source to the drain is characterized by spacing distance between a gate dielectric of the gate and a drain contact of the drain being greater than a spacing distance between a source contact of the source and the drain contact of the drain.

The field effect transistor also includes a substrate; a silicon carbide semiconductor layer formed over the substrate; a source formed in the semiconductor layer; a drain formed in the semiconductor layer, whereon the drain is disposed laterally relative to the source. The transistor also includes a P well formed about the source, where the P well is spaced apart from the drain; and a gate having gate dielectric, where a spacing distance between a gate dielectric of the gate and a drain contact of the drain is greater than a spacing distance between a source contact of the source and the drain contact of the drain.

Embodiments herein recognize that silicon carbide (SiC) provides a wide-bandgap semiconductor material that features superior electrical properties when compared to gate unshielded silicon (Si) material for targeted applications. SiC exhibits considerable advantages over Si for certain applications, such as a higher thermal conductivity, a larger critical electric field, and a higher breakdown voltage, making it a compelling candidate for high-power and high-temperature applications. Embodiments herein recognize that SiC-based power devices can exhibit increased efficiency, reduced switching losses, and superior performance compared to their Si-based counterparts, resulting in significant advancements in the field of power electronics [1] for certain applications. Accordingly, practicing embodiments herein with SiC can provide advantages for certain applications.

In one aspect, embodiments herein can provide silicon carbide (SiC)-based power integrated circuits (ICs) that unite the advantages of SiC power devices with those of integrated circuit (IC) technology, such as superior reliability and performance, reduced weight, size, and cost. Embodiments herein can be incorporated into applications demanding high efficiency and reliability, such as renewable energy systems, electric vehicles, and industrial motor drives, where high-power and high-voltage are required. Embodiments herein featuring HV Power ICs in SiC can be incorporated for use in high-power and high-temperature applications.

Certain embodiments herein provide fully integrated high voltage (HV) silicon carbide (SiC) power MOSFET integrated circuits (ICs). Embodiments herein can include monolithically integrating the HV power nMOSFET and low-voltage (LV) complementary metal oxide semiconductor (CMOS) circuitry onto a single chip utilizing a single process flow and multi-metal stack was verified on an N− epi/N+ substrate, as illustrated in [3]. To address isolation between the voltage-differential regions of a wafer based structure, an epitaxial (epi) layer stack can be re-engineered and fine-tuned to an N-epi/P− epi/N+ substrate configuration, which allows for complete isolation of the HV blocks while still being integrated with the LV CMOS [4].

While embodiments herein refer to integrated circuits, circuit structures set forth herein can alternatively define discrete devices. Embodiments of HV nMOSFETs herein can be provided as discrete devices or can be incorporated into integrated circuits. In HV nMOSFETs herein can be integrated into HV power integrated circuits (ICs) in 4H—SiC. Embodiments herein recognize that HV nMOSFETs, e.g., as reported in [3], [4], [5], and [6] can exhibit substantial leakage during their operation. Embodiments herein improve design architecture for lateral MOSFETs, which effectively addresses the leakage issue while simultaneously achieving increased breakdown voltage.

Additional aspects and features of system 200 are set forth with reference to the following examples.

### Example 1

Integrated circuits according to the design of FIGS. 1A and 1D, respectfully were subject to simulation and fabricated product testing, respectively. Specifications for the MOSFETs of the various designs were as follows.

TABLE B
(FIG. 1A design with gate shielding)

| Parameter | Value |
|---|---|
| N-epi | 2.5 μm; 6.5e16 cm⁻³ |
| P-epi | 6 μm; 2e16 cm⁻³ |
| Channel | 0.5 μm |
| JFET (Ljfet) | 0.6 μm |
| Ptop (Lptop) | 4.0 μm |
| Gap (Lgap) | 1.5 μm |
| P+ Source | 1.0 μm |
| N+ Source | 2.1 μm |

TABLE C
(FIG. 1D design without gate shielding)

| Parameter | Value |
|---|---|
| N-epi | 2.5 μm; 6.5e16 cm⁻³ |
| P-epi | 6 μm; 2e16 cm⁻³ |
| Channel | 0.5 μm |
| JFET (Ljfet) | 2.0 μm |
| Ptop (Lptop) | 4.0 μm |
| Gap (Lgap) | 1.5 μm |
| P+ Source | 0.75 μm |
| N+ Source | 1.6 μm |

The sample of Table B (FIG. 1D without gate shielding) was fabricated and measured to have a breakdown voltage of 480V while the simulated sample featuring the gate shielded architecture was determined to have a greater breakdown voltage of 850V in spite of having a smaller X-Y plane footprint. The preliminary results indicating that the FIG. 1A design can achieve improved performance with economized X-Y plane consumption (economized pitch) were verified with sample fabrication and testing set forth in reference to Example 2.

### End of Example 1

### Example 2

In Example 2, testing results are compared for fabricated devices fabricated according the gate unshielded architecture of FIG. 1D and the gate shielded architecture of FIG. 1A. The starting material for the reported device fabrication process consisted of a 4-inch N+ substrate covered by a 6 μm thick P-epi layer doped with 2×1016 cm−3, followed by a 2.5 μm thick N-epi layer doped with 6.5×1016 cm−3.

### Ion-Implantation

All of the p-type regions in the HV nMOSFETs were formed by Aluminum ion implants. The n-type regions were formed by Nitrogen ion implants. Subsequent to the ion implantation process, the wafers were subjected to annealing at 1650° C. for 10 min with a carbon cap to activate the implanted aluminum and nitrogen ions.

### Gate Oxide and Gate Poly Formation

The gate oxide with a desired thickness of 50 nm was formed through the thermal oxidation process, followed by a post-oxidation annealing (POA) step conducted for 180 minutes under NO atmosphere. A gate polysilicon layer of 0.5 μm thickness was deposited, doped with phosphorus, and subsequently patterned after the formation of the gate oxide layer.

### Ohmic and Metal Processing

After the gate formation, ohmic contacts were established by depositing 1000 μA of Nickel, followed by annealing at 750° C. for 2 min to form Nickel silicide. Further annealing was performed at 1000° C. for 2 min to achieve optimum contact resistance. Subsequently, a 0.5 μm Aluminum was deposited, patterned, and etched to form the metal layers.

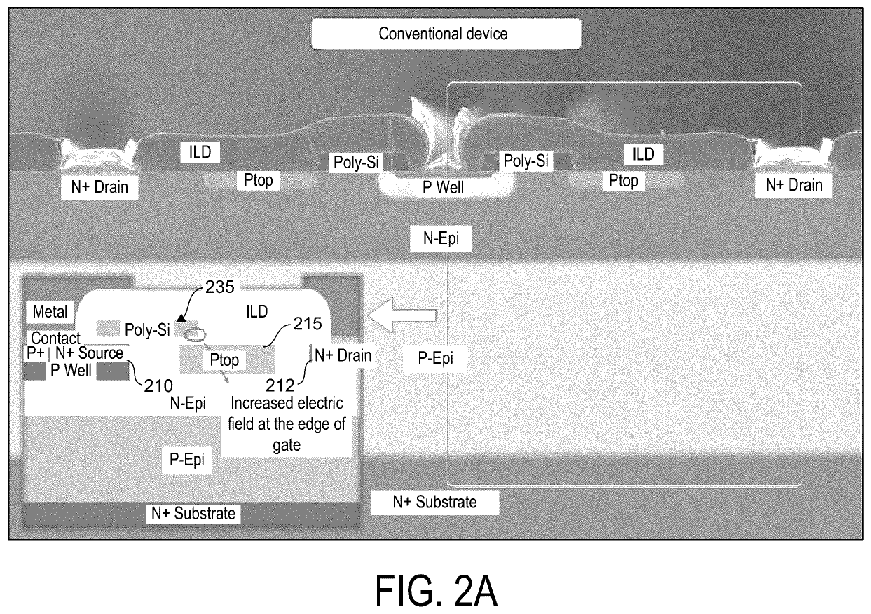

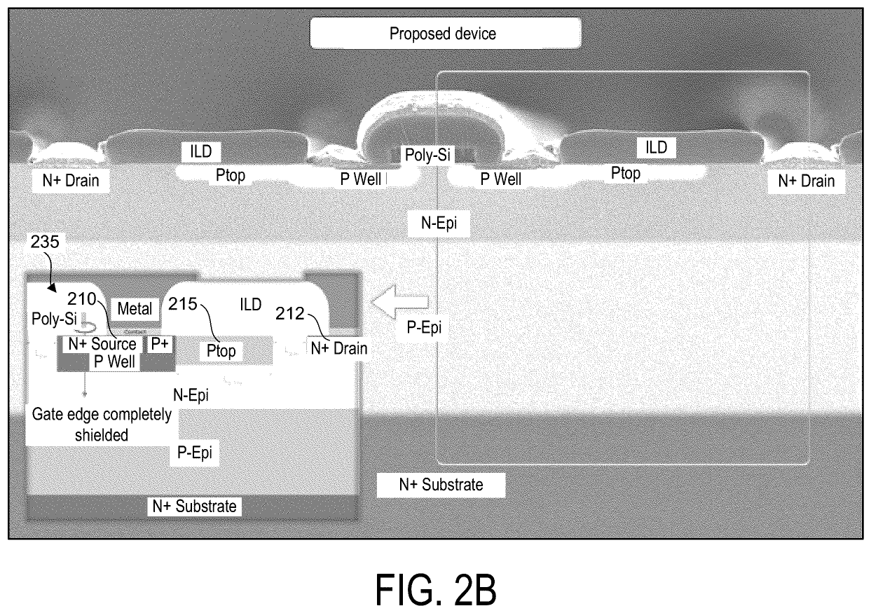

FIG. 2A: SEM cross-section of the gate unshielded device and inset shows the schematic cross-section. As seen in the schematic, the area at the edge of the gate electrode is where there will be an increase in the electric field leading to an increase in the gate leakage.

FIG. 2B: SEM cross-section of the gate shielded device and the inset shows the schematic cross-section. As seen in the schematic, the gate electrode is completely shielded from the P top region and hence is unaltered by the design of the P top leading to effective distribution of electric field in the gate oxide.

### Results and Analysis

The SEM and schematic cross-section of the gate unshielded HV lateral nMOSFETs are shown in FIG. 2A. P top region 215 which in Example 2 is aluminum implanted is employed to minimize the surface electric field while simultaneously amplifying the breakdown voltage of the device. The design of the P top region 215 (length and dose) is extremely critical in determining the blocking capability of the lateral device. The length of the P top region 215 for both gate unshielded and gate shielded devices reported in this work is the same at 4 μm. The dose of the P top region 215, in particular, should be carefully designed so that it is not fully depleted leading to a significant increase in the electric field at the edge of the gate electrode. Although the designs are well optimized using the 2-D TCAD simulations, due to the process variations and incomplete ionization of the holes, the P top dose cannot be precisely controlled. Hence, the gate unshielded design is susceptible to increasing the electric field at the edge of the gate and consequently increasing the leakage. However, with the optimized gate shielded design (FIG. 2B), the gate shielded device thoroughly eliminates the shortcomings of the gate unshielded device leading to enhanced performance in the blocking mode of operation. The SEM and the schematic cross-section of the gate shielded device with the new architecture are illustrated in FIG. 2B. The new architecture incorporates a design where the gate is completely shielded and isolated from the P top region 215. So, any process or uncontrollable dose variations in the P top region 215 helps the gate current stay unaffected leading to low leakage during the blocking mode of operation. Additionally, the gate shielded architecture mitigates the prominent surface field management issues that commonly arise in lateral MOSFET designs. The gate-channel-JFET areas of the gate shielded design bear a striking resemblance to those of vertical MOSFETs, which enables the application of similar techniques to enhance field management, reliability, and ruggedness. As a result, this novel architecture presents an excellent solution for the design of lateral MOSFETs. Through further optimization, the gate shielded device's cell pitch can be reduced when compared to a gate unshielded device.

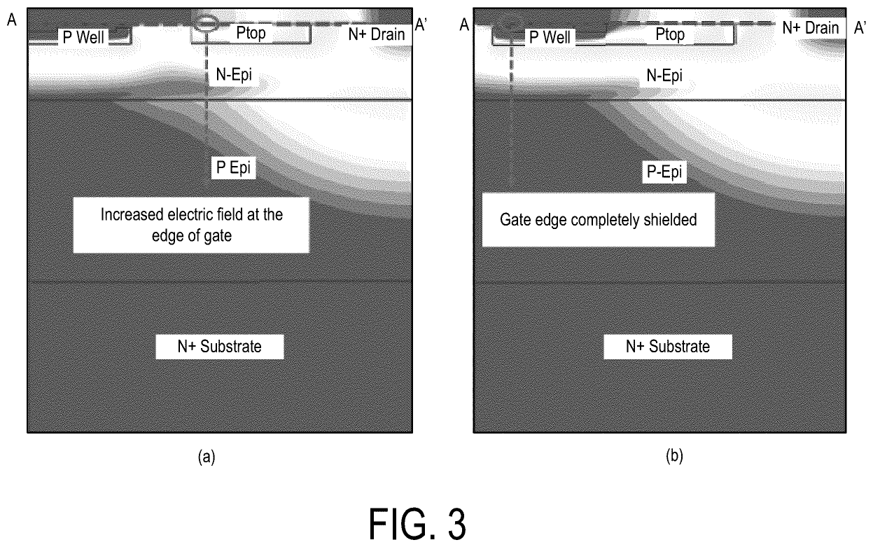

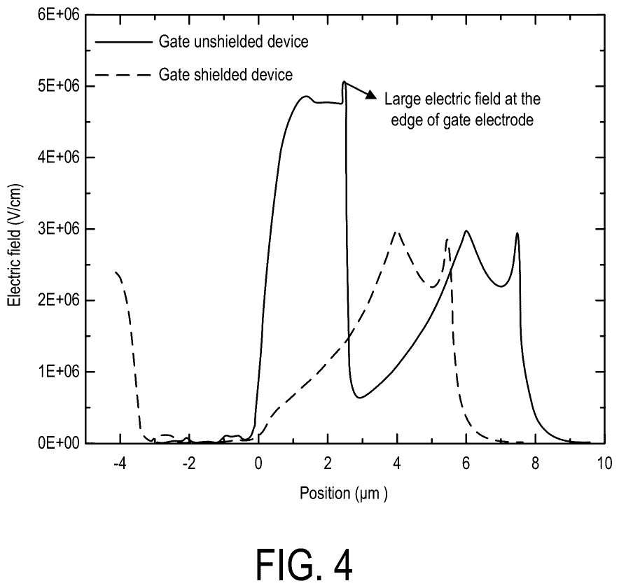

FIG. 3 and FIG. 4 depict the simulated cross-sections and the corresponding electric field profiles along the gate for gate unshielded and gate shielded HV nMOSFETs (in accordance with the gate unshielded design of FIG. 1D and gate shielded defined of FIG. 1A respectively). As seen in FIG. 4, the gate unshielded device shows a larger electric field at the edge of the gate while the gate shielded device exhibits a lower electric field along the gate and across the gate oxide (A-A′).

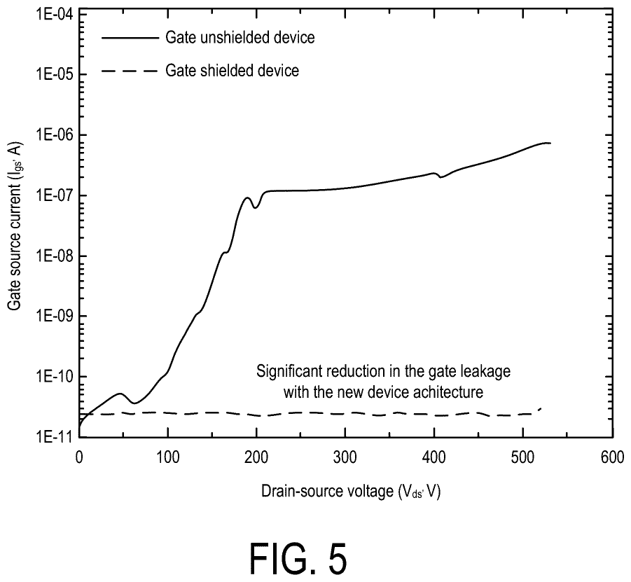

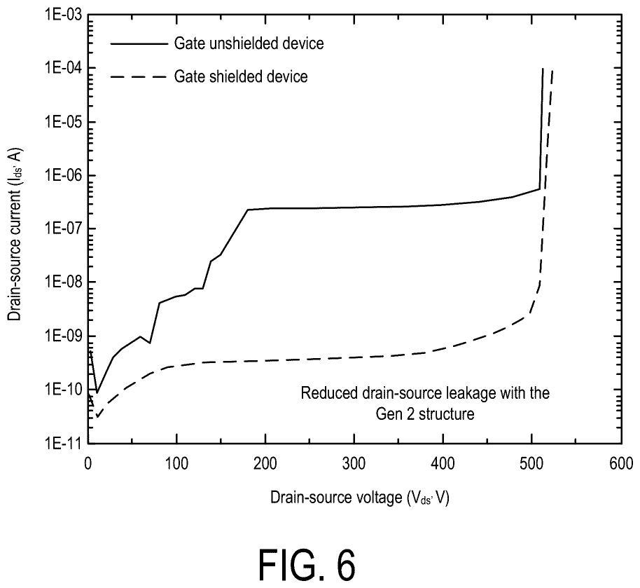

The measured gate-source leakage from the gate unshielded and the gate shielded devices are shown in FIG. 5. The gate current from the gate unshielded device significantly increases as the charges in the Ptop are being depleted with the increase in the drain voltage while the gate current from the gate shielded device remains unaltered. FIG. 6 shows the measured drain-source leakages from the gate unshielded and gate shielded HV nMOSFETs. As anticipated, due to the gate-source leakage the overall drain-source leakage increases for the gate unshielded device but it remains the same across the voltage range for the gate shielded devices. Hence, the results demonstrate that the gate shielded device design for the lateral nMOSFET is effective in suppressing the gate leakage current and providing enhanced performance by suppressing the leakage as compared to the gate unshielded design.

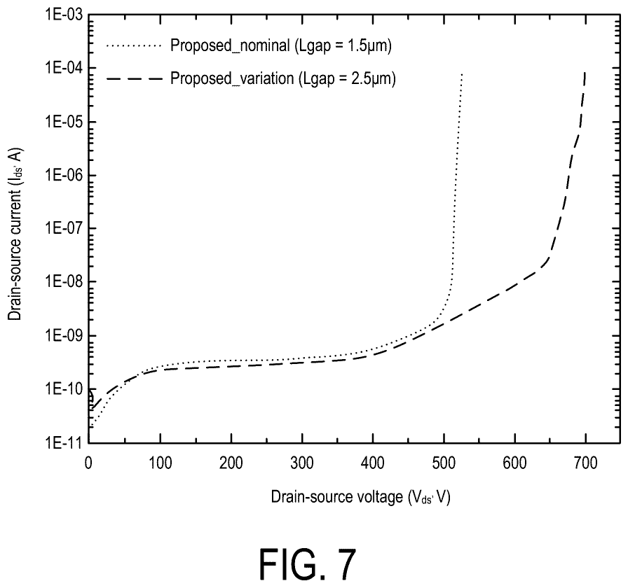

The critical dimensions (dimensions shown in FIG. 2B) to improve the breakdown voltage of the gate shielded HV lateral nMOSFETs are to vary the length of the P top region 215 (Lptop) and the gap between Ptop region 215 and the N+ drain (Lgap). Increasing Lptop or Lgap increases the distance between the source and drain facilitating an effective distribution of electric field leading to enhancement in the breakdown voltage [7]. However, the cell pitch of the device will be linearly increased with the increase in the dimensions of Lptop or Lgap. Hence, in this work, with a deviation from the nominal parameters (Lptop=4 μm and Lgap=1.5 μm), utilizing the gate shielded device design, a variation in the increase (1.5 μm to 2.5 μm) in Lgap resulted in a breakdown voltage as high as 700V at a drain-source current of 100 μA demonstrating a voltage-supporting capability of 107.6 V/μm in the lateral direction as shown in FIG. 7.

In conclusion, this example demonstrates an architecture that effectively suppresses the leakage current from high-voltage lateral MOSFETs in 4H—SiC. The fabricated gate shielded MOSFETs were evaluated and compared with the gate unshielded architecture, demonstrating a substantial reduction in the leakage current. These outcomes confirm the effectiveness of the gate shielded design architecture, which meets the requirements for a durable lateral power MOSFET, suitable for use in the development of SiC power integrated circuits. This research provides valuable insights into the evolution of advanced SiC power electronics that can lead to more efficient and reliable power conversion systems in the future.

This example demonstrates and presents an enhanced design architecture to suppress the leakage from the high-voltage (HV) lateral MOSFETs in 4H—SiC. The demonstrated MOSFETs were fabricated on an N-epi/P-epi/N+ substrate. A comparative analysis was conducted between the performance of the improved desig architecture and the gate unshielded architecture, and the outcomes exhibit a notable decrease in the magnitude of the leakage current. The gate shielded device architecture possesses the capability to effectively fulfill the design specifications of a durable lateral power MOSFET to be used in silicon carbide (SiC) power integrated circuits (ICs).

### End of Example 2

It should be appreciated that all combinations of the foregoing concepts and additional concepts discussed in greater detail below (provided such concepts are not mutually inconsistent) are contemplated as being part of the subject matter disclosed herein. In particular, all combinations of claims subject matter appearing at the end of this disclosure are contemplated as being part of the subject matter disclosed herein. It should also be appreciated that terminology explicitly employed herein that also may appear in any disclosure incorporated by reference should be accorded a meaning most consistent with the particular concepts disclosed herein.

This written description uses examples to disclose the subject matter, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

It is to be understood that the above description is intended to be illustrative, and not restrictive. For example, the above-described examples (and/or aspects thereof) may be used in combination with each other. In addition, many modifications may be made to adapt a particular situation or material to the teachings of the various examples without departing from their scope. While the dimensions and types of materials described herein are intended to define the parameters of the various examples, they are by no means limiting and are merely exemplary. Many other examples will be apparent to those of skill in the art upon reviewing the above description. The scope of the various examples should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Forms of term “based on” herein encompass relationships where an element is partially based on as well as relationships where an element is entirely based on. Forms of the term “defined” encompass relationships where an element is partially defined as well as relationships where an element is entirely defined. Further, the limitations of the following claims are not written in means-plus-function format and are not intended to be interpreted based on 35 U.S.C. § 112(f) unless and until such claim limitations expressly use the phrase “means for” followed by a statement of function void of further structure. It is to be understood that not necessarily all such objects or advantages described above may be achieved in accordance with any particular example. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

The terms “substantially”, “approximately”, “about”, “relatively”, or other such similar terms that may be used throughout this disclosure, including the claims, are used to describe and account for small fluctuations, such as due to variations in processing, from a reference or parameter. Such small fluctuations include a zero fluctuation from the reference or parameter as well. For example, they can refer to less than or equal to ±10%, such as less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%. If used herein, the terms “substantially”, “approximately”, “about”, “relatively,” or other such similar terms may also refer to no fluctuations, that is, ±0%. It is contemplated that numerical values, as well as other values that are recited herein can be modified by the term “about”, whether expressly stated or inherently derived by the discussion of the present disclosure. Further, any description of a range herein can encompass all subranges.

The terms “connect,” “connected,” “contact” “coupled” and/or the like are broadly defined herein to encompass a variety of divergent arrangements and assembly techniques. These arrangements and techniques include, but are not limited to (1) the direct joining of one component and another component with no intervening components therebetween (i.e., the components are in direct physical contact); and (2) the joining of one component and another component with one or more components therebetween, provided that the one component being “connected to” or “contacting” or “coupled to” the other component is somehow in operative communication (e.g., electrically, fluidly, physically, optically, etc.) with the other component (notwithstanding the presence of one or more additional components therebetween). It is to be understood that some components that are in direct physical contact with one another may or may not be in electrical contact and/or fluid contact with one another. Moreover, two components that are electrically connected, electrically coupled, optically connected, optically coupled, fluidly connected or fluidly coupled may or may not be in direct physical contact, and one or more other components may be positioned therebetween.

While the subject matter has been described in detail in connection with only a limited number of examples, it should be readily understood that the subject matter is not limited to such disclosed examples. Rather, the subject matter can be modified to incorporate any number of variations, alterations, substitutions or equivalent arrangements not heretofore described, but which are commensurate with the spirit and scope of the subject matter. Additionally, while various examples of the subject matter have been described, it is to be understood that aspects of the disclosure may include only some of the described examples. Also, while some examples are described as having a certain number of elements it will be understood that the subject matter can be practiced with less than or greater than the certain number of elements. Accordingly, the subject matter is not to be seen as limited by the foregoing description, but is only limited by the scope of the appended claims.

The following references are incorporated by reference in their entireties and a skilled person is considered to be aware of disclosure of these references.

### REFERENCES

J. W. Palmour et al., “Silicon carbide power MOSFETs: Breakthrough performance from 900 V up to 15 kV,” in 2014 IEEE 26th International Symposium on Power Semiconductor Devices & IC's (ISPSD), June 2014, pp. 79-82. doi: 10.1109/ISPSD.2014.6855980.
D. Disney and Z. J. Shen, “Review of Silicon Power Semiconductor Technologies for Power Supply on Chip and Power Supply in Package Applications,” IEEE Trans. Power Electron., vol. 28, no. 9, pp. 4168-4181, 2013, doi: 10.1109/TPEL.2013.2242095.
S. B. Isukapati et al., “Monolithic Integration of Lateral HV Power MOSFET with LV CMOS for SiC Power IC Technology,” in 2021 33rd International Symposium on Power Semiconductor Devices and ICs (ISPSD), May 2021, pp. 267-270. doi: 10.23919/ISPSD50666.2021.9452235.
S. B. Isukapati et al., “Development of Isolated CMOS and HV MOSFET on an N− epi/P− epi/4H—SiC N+ Substrate for Power IC Applications,” in 2021 IEEE 8th Workshop on Wide Bandgap Power Devices and Applications (WiPDA), November 2021, pp. 118-122. doi: 10.1109/WiPDA49284.2021.9645134.
S. B. Isukapati, A. J. Morgan, and W. Sung, “Edge Termination and Peripheral Designs for SiC High-Voltage (HV) Lateral MOSFETs for Power IC Technology,” in 2022 IEEE 34th International Symposium on Power Semiconductor Devices and ICs (ISPSD), May 2022, pp. 213-216. doi: 10.1109/ISPSD49238.2022.9813635.
S. B. Isukapati, S. Yup Jang, and W. Sung, “Area-Efficient High-Voltage (HV) Lateral MOSFETs for Discrete Device Development and Power IC Integration,” in 2022 IEEE 9th Workshop on Wide Bandgap Power Devices & Applications (WiPDA), November 2022, pp. 122-126. doi: 10.1109/WiPDA56483.2022.9955284.
N. Yun and W. Sung, “Design and Fabrication Approaches of 400-600 V 4H—SiC Lateral MOSFETs for Emerging Power ICs Application,” IEEE Transactions on Electron Devices, vol. 67, no. 11, pp. 5005-5011, 2020.
Isukapati, Sundar Babu, Hua Zhang, Tianshi Liu, Emran Ashik, Bongmook Lee, Adam J Morgan, Woongje Sung, Ayman Fayed, and Anant K. Agarwal, “Monolithic Integration of Lateral HV Power MOSFET with LV CMOS for SiC Power IC Technology,” in 2021 33rd International Symposium on Power Semiconductor Devices and ICs (ISPSD), May 2021, pp. 267-270. doi: 10.23919/ISPSD50666.2021.9452235.
Isukapati, Sundar Babu, Adam J Morgan, Woongje Sung, Hua Zhang, Tianshi Liu, Ayman Fayed, Anant K. Agarwal, Emran Ashik, and Bongmook Lee, “Development of Isolated CMOS and HV MOSFET on an N− epi/P− epi/4H—SiC N+ Substrate for Power IC Applications,” in 2021 IEEE 8th Workshop on Wide Bandgap Power Devices and Applications (WiPDA), November 2021, pp. 118-122. doi: 10.1109/WiPDA49284.2021.9645134.
M. Okamoto, A. Yao, H. Sato, and S. Harada, “First Demonstration of a Monolithic SiC Power IC Integrating a Vertical MOSFET with a CMOS Gate Buffer,” in 2021 33rd International Symposium on Power Semiconductor Devices and ICs (ISPSD), May 2021, pp. 71-74. doi: 10.23919/ISPSD50666.2021.9452262.
X. Li, N. Amirifar, K. Geens, M. Zhao, W. Guo, et al., “GaN-on-SOL: Monolithically Integrated All-GaN ICs for Power Conversion,” in 2019 IEEE International Electron Devices Meeting (IEDM), December 2019, pp.40.4.1-4.4.4. doi: 10.1109/IEDM19573.2019.8993572.
S. B. Isukapati, A. J. Morgan and W. Sung, “Edge Termination and Peripheral Designs for SiC High-Voltage (HV) Lateral MOSFETs for Power IC Technology,” 2022 IEEE 34th International Symposium on Power Semiconductor Devices and ICs (ISPSD), Vancouver, BC, Canada, 2022, pp. 213-216,.
S. B. Isukapati, S. Y. Jang and W. Sung, “Enhanced Design Architecture to Suppress Leakage Current of High-Voltage (HV) Lateral nMOSFETs in 4H—SiC,” 2023 35th International Symposium on Power Semiconductor Devices and ICs (ISPSD), Hong Kong, 2023, pp. 358-361.

What is claimed is:

1. A field effect transistor comprising:
a substrate;
a semiconductor layer formed over the substrate;
a source formed in the semiconductor layer;
a drain formed in the semiconductor layer, whereon the drain is disposed laterally relative to the source; and
a gate;
wherein a spacing distance of the gate to the drain is greater than a spacing distance of the source to the drain.

2. The field effect transistor of claim 1, wherein the field effect transistor includes a P well formed about the source, the P well spaced apart from the drain.

3. The field effect transistor of claim 1, wherein a spacing distance between a gate dielectric of the gate and a drain contact of the drain is greater than a spacing distance between a source contact of the source and the drain contact of the drain.

4. The field effect transistor of claim 1, wherein a source contact of the source, a drain contact of the drain, and the gate dielectric extend at a common elevation, wherein a spacing distance between a gate dielectric of the gate aligned under a gate electrode of the gate and a drain contact of the drain is greater than a spacing distance between a source contact of the source and the drain contact of the drain.

5. The field effect transistor of claim 1, wherein the semiconductor layer is a doped silicon carbide layer.

6. The field effect transistor of claim 1, wherein the gate includes a first side edge and an opposite second side edge, wherein the first side edge of the gate is aligned over the source, and wherein the opposite second side edge of the gate is aligned over the source.

7. The field effect transistor of claim 1, wherein the source includes a first drain side edge and an opposite second side edge, wherein the first drain side edge of the source is closer to the drain than the second opposite side edge of the source, and wherein the second opposite side edge of the source is aligned under the gate.

8. The field effect transistor of claim 1, wherein the semiconductor layer is an epitaxially grown doped silicon carbide layer.

9. The field effect transistor of claim 1, wherein the semiconductor layer is a silicon carbide layer.

10. The field effect transistor of claim 1, wherein the semiconductor layer is a silicon carbide layer, wherein a source contact of the source, a drain contact of the drain, and the gate dielectric extend at a common elevation, wherein a spacing distance between a gate dielectric of the gate and a drain contact of the drain is greater than a spacing distance between a source contact of the source and the drain contact of the drain, wherein the field effect transistor includes a P well formed about the source, the P well being spaced apart from the drain.

11. The field effect transistor of claim 1, wherein the semiconductor layer is an epitaxially grown doped silicon carbide layer.

12. The field effect transistor of claim 1, wherein the source is disposed intermediate the gate and the drain.

13. An integrated circuit incorporating the field effect transistor of claim 1, wherein the source, the drain and the gate define a high voltage power MOSFET region, and wherein the integrated circuit includes a low voltage CMOS region, the low voltage CMOS region including a low voltage NMOS region, and a low voltage PMOS region, wherein the low voltage CMOS region is defined by the substrate and the semiconductor layer.

14. An integrated circuit incorporating the field effect transistor of claim 1, wherein the source, the drain and the gate define a high voltage power MOSFET region, and wherein the integrated circuit includes a low voltage CMOS region, the low voltage CMOS region including a low voltage NMOS region, and a low voltage PMOS region, wherein the low voltage CMOS region is defined by the substrate and the semiconductor layer, wherein the integrated circuit includes a doped formation isolating the high voltage power MOSFET region from the low voltage CMOS region, the doped formation extending an entire depth of the semiconductor layer, and being formed by use of channel ion implantation.

15. An integrated circuit incorporating the field effect transistor of claim 1, wherein the source, the drain and the gate define a high voltage power MOSFET region, and wherein the integrated circuit includes a low voltage CMOS region, the low voltage CMOS region including a low voltage NMOS region, and a low voltage PMOS region, wherein the low voltage CMOS region is defined by the substrate and the semiconductor layer, wherein the integrated circuit includes a doped formation isolating the high voltage power MOSFET region from the low voltage CMOS region, the doped formation extending an entire depth of the semiconductor layer, and being formed by use of channel ion implantation, wherein the integrated circuit includes a second doped formation isolating the low voltage NMOS region, and the low voltage PMOS region, the second doped formation extending an entire depth of the semiconductor layer, and being formed by use of channel ion implantation, wherein the semiconductor layer is a silicon carbide layer, wherein a source contact of the source, a drain contact of the drain, and the gate dielectric extend at a common elevation, wherein a spacing distance between a corner of a gate electrode of the gate adjacent the gate dielectric and a drain contact of the drain is greater than a spacing distance between a source contact of the source and the drain contact of the drain, wherein the field effect transistor includes a P well formed about the source, the P well being spaced apart from the drain, wherein the gate includes a first side edge and an opposite second side edge, wherein the first side edge of the gate is aligned over the source, and wherein the opposite second side edge of the gate is aligned over the source, wherein the source includes a first drain side edge and an opposite second side edge, wherein the first drain side edge of the source is closer to the drain than the second opposite side edge of the source, and wherein the second opposite side edge is aligned under the gate.

16. A field effect transistor comprising:
a substrate;
a semiconductor layer formed over the substrate;
a source formed in the semiconductor layer;
a drain formed in the semiconductor layer, whereon the drain is disposed laterally relative to the source;
a gate having a gate dielectric; and
wherein the field effect transistor is operative in a blocking mode in which the field effect transistor supports a blocking mode drain voltage, and wherein the field effect transistor includes shielding so that the gate is shielded from the blocking mode drain voltage.

17. The field effect transistor of claim 16, wherein the shielding is characterized by a spacing distance of the gate to the drain being greater than a spacing distance of the source to the drain.

18. The field effect transistor of claim 16, wherein the shielding is characterized by a spacing distance between a gate dielectric of the gate and a drain contact of the drain being greater than a spacing distance between a source contact of the source and the drain contact of the drain.

19. The field effect transistor of claim 16, wherein the field effect transistor is configured so that in the blocking mode, the source and the gate are grounded, wherein the shielding is characterized by a spacing distance of the gate to the drain being greater than a spacing distance of the source to the drain, wherein the spacing distance of the gate to the drain being greater than a spacing distance of the source to the drain is characterized by spacing distance between a gate dielectric of the gate and a drain contact of the drain being greater than a spacing distance between a source contact of the source and the drain contact of the drain.

20. A field effect transistor comprising:
a substrate;
a silicon carbide semiconductor layer formed over the substrate;
a source formed in the silicon carbide semiconductor layer;
a drain formed in the silicon carbide semiconductor layer, whereon the drain is disposed laterally relative to the source;
a P well formed about the source, wherein the P well is spaced apart from the drain; and
a gate having gate dielectric; and
wherein a spacing distance between the gate dielectric of the gate and a drain contact of the drain is greater than a spacing distance between a source contact of the source and the drain contact of the drain.
